(19) United States
(12) Patent Application Publication
(10) Pub. No.: US 2012/0119183 A1
(43) Pub. Date: May 17, 2012

(54) FABRICATION OF AN INTEGRATED TERAHERTZ SOURCE USING FIELD EMITTER ARRAY WITH GRATING STRUCTURE

(76) Inventors: Boris G. Kharas, Brooklyn, NY (US); Robert Amantea, Manalapan, NJ (US); Pradyumna Kumar Swain, Princeton, NJ (US)

(21) Appl. No.: 11/832,435

(22) Filed: Aug. 1, 2007

Related U.S. Application Data
(60) Provisional application No. 60/834,727, filed on Aug. 1, 2006.

(51) Int. Cl. H01L 29/06; H01L 21/20

(52) U.S. Cl. 257/10; 438/20; 257/E21.09; 257/E29.005

(57) ABSTRACT

The present invention provides for a fabrication of an integrated THz source. The fabrication includes integrating a field emitter array (FEA) with a grating by utilizing micro-electromechanical system (MEMS) and grating fabrication methods to build the FEA device upon a moveable surface that can be rotated perpendicular to the other, and locked into alignment or alternately finely adjusted.

### CROSS-REFERENCE TO RELATED APPLICATIONS

This application claims the benefit of U.S. Provisional Patent Application No. 60/834,727 filed Aug. 1, 2006, the entire disclosure of which is incorporated herein by reference.

### FIELD OF THE INVENTION

The present invention relates generally relates to a field of Terahertz (THz) technology and more particularly to the fabrication of a Smith Purcell THz type source with Field Emitter Array (FEA) electron source integrated with a self aligned grating for a chip scale terahertz radiation source.

### BACKGROUND OF THE INVENTION

A low cost, compact, (chip scale) mm wave and THz source has been a goal for realizing inexpensive THZ systems for many technologies including imaging, spectroscopy, chemical warfare and bomb detection systems. Smith Purcell type terahertz sources require two components in very tight mechanical alignment: an electron beam emitter and a millimeter scale metallic grating. Conventional ribbon electron beam sources are expensive, custom built assemblies that can measure several inches, and need to be mechanically aligned to the millimeter scale metal gratings using expensive fixtures and micro-motors. To realize a chip scale THz source requires a micro-fabricated electron emitter, an on-wafer fabricated metallic grating, and a scheme to align the two so that the electron source is perpendicular to the plane of the grating surface. Although chip scale electron source, and small metallic components have historically been fabricated, a combination of the two has not to our knowledge been achieved, nor combined in a scheme that would allow the emitter to be intrinsically aligned to the grating.

Chip based electron field emitters arrays have been fabricated by many research and industry groups and generally consist of arrays of sharp silicon or refractory metal electron emitter tips, typically measuring 0.5 to 3 microns in height and diameter with a sub-micron tip radius. Surrounding each tip is an oxide insulator, and above it a metal or silicon gate electrode that is used for electron extraction and focusing. The push to reduce turn-on voltages, improve electron beam current uniformity, and device lifetime has lead to the study of a wide variety of emitter materials and process variations, with the general goal of increasing tip sharpness for reduction of electron extraction fields. FEAs are built using traditional semiconductor processing techniques, which lend themselves to high volume and high mechanical tolerance fabrication. The wafer level fabrication of metallic parts with very high aspect ratio's and smooth sidewalls can be achieved using the LIGA method. LIGA is a German acronym for Lithographische Galvanoformung Abformung, which translates to Lithographic, electroplating and molding. The technique uses a synchrotron x-ray source to expose a thick resist, that is subsequently filled with metal by electroplating. LIGA components can be integrated with other micro-fabricated or micro-electromechanical (MEMS) parts so long as there is no threat of damage to the electronic parts from the high flux x-ray radiation.

Non chip scale Oratron's require manual assembly of the electron gun and grating components and subsequent alignment to maximize gain. Additionally, the fine pitch required for gratings for mm wavelength Thz radiation applications demand tooth pitches on the scale of ¼ wavelength, or approx. 125 μm and tooth gaps on the order of 30-80 μm. These grating dimensions are difficult to achieve using traditional machining techniques, but are ideally suited for LIGA fabrication.

Thus, there is a need in the art to provide an improved fabrication of a THz source using FEA with grating structure to overcome the disadvantages of the prior art.

### SUMMARY OF THE INVENTION

The present invention provides a method for fabrication of an integrated terahertz source. The method comprise providing a SOI substrate having a buried oxide layer and depositing a SCS layer with at least one trench portion substantially on the buried oxide of the SOI substrate. The method also comprise constructing a FEA device substantially in the at least one trench portion of the SCS layer of the SOI substrate and creating a grating on the at least one trench portion of the SCS layer adjacent to the FEA device. The method further comprises positioning of the FEA device in an angular alignment with the grating.

The present invention also provides an integrated THz source structure comprising a SOI substrate having a buried oxide layer and an SCS layer having at least one trench portion deposited substantially on the buried oxide layer of the SOI substrate. The structure also comprise a FEA device constructed substantially in at least one trench portion of the SCS layer of the SOI substrate and a grating created on the at least one trench portion of the SCS layer adjacent to the FEA device. The FEA device is positioned in an angular alignment with the grating.

### BRIEF DESCRIPTION OF THE DRAWINGS

FIG. 1 illustrates a schematic configuration of an integration process for combining silicon FEA device on SOI with MEMS actuation and LIGA grating in accordance with the embodiment of the present invention.

FIG. 2A illustrates a schematic configuration of a process to fabricate FEA device of FIG. 1.

FIG. 2B illustrates a schematic configuration of a top-down view of the integrated FEA device fabricated in FIG. 2A.

FIG. 3A illustrates a schematic configuration of a fabrication for SOI with the multi level polysilicon surface micromachining MEMS device of FIG. 1.

FIG. 3B illustrates a schematic configuration of the electrodes and the FEA tips of FIG. 3A.

FIG. 3C illustrates a schematic configuration of a top-down view of FEA/MEMS device after completion of surface micromachining in FIG. 3A.

FIG. 4 illustrates a schematic configuration of a process to fabricate LIGA grating of FIG. 1.

FIG. 5 illustrates a schematic configuration of the FEA/MEMS device with respect to the LIGA alignment of FIG. 1.

It is understood that the attached drawings are for the purpose of illustrating the concepts of the invention and may not be to scale.

### DETAILED DESCRIPTION OF THE INVENTION

In one embodiment of the present invention, the realizing of the integration of a field emitter array (FEA) electron source with a grating is achieved by utilizing micro-electromechanical system (MEMS) and LIGA fabrication methods to build the FEA (or grating) upon a moveable surface that can be rotated perpendicular to the other, and locked into alignment or alternately finely adjusted. This approach of self-alignment of the grating to the electron gun reduces Orotron (intra-cavity high resolution spectrometer) THz source assembly time and alignment complexity. Furthermore, it creates a shaped cold cathode emitter that is suitable for producing a ribbon (high aspect ratio of width to thickness) electron beam.

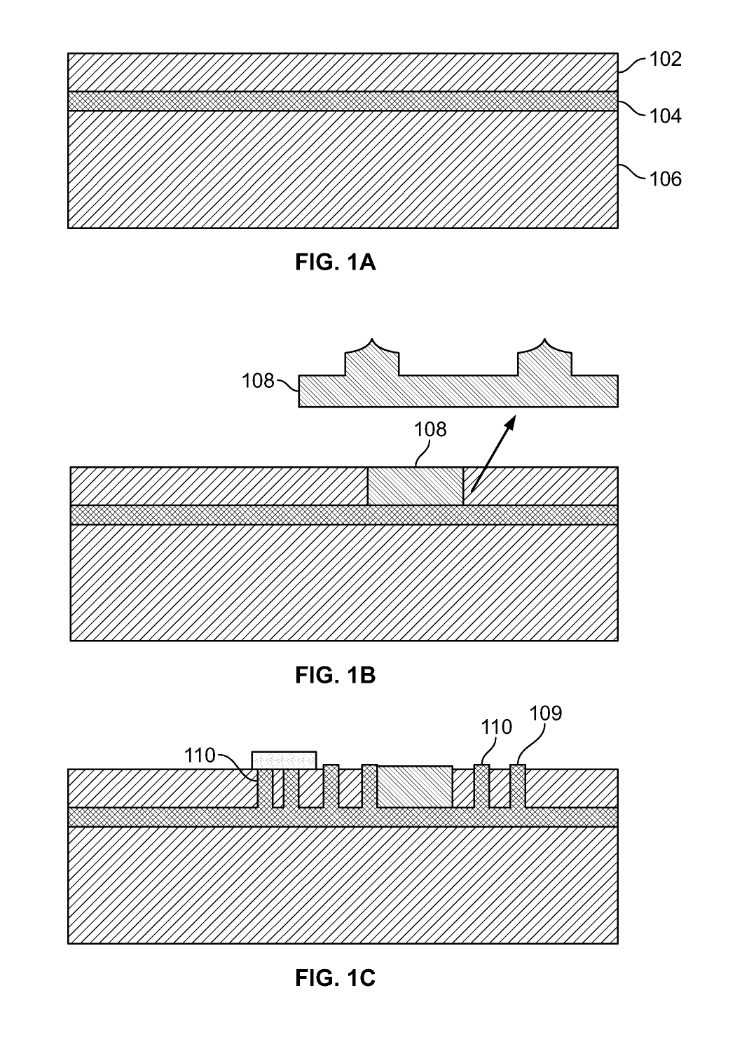

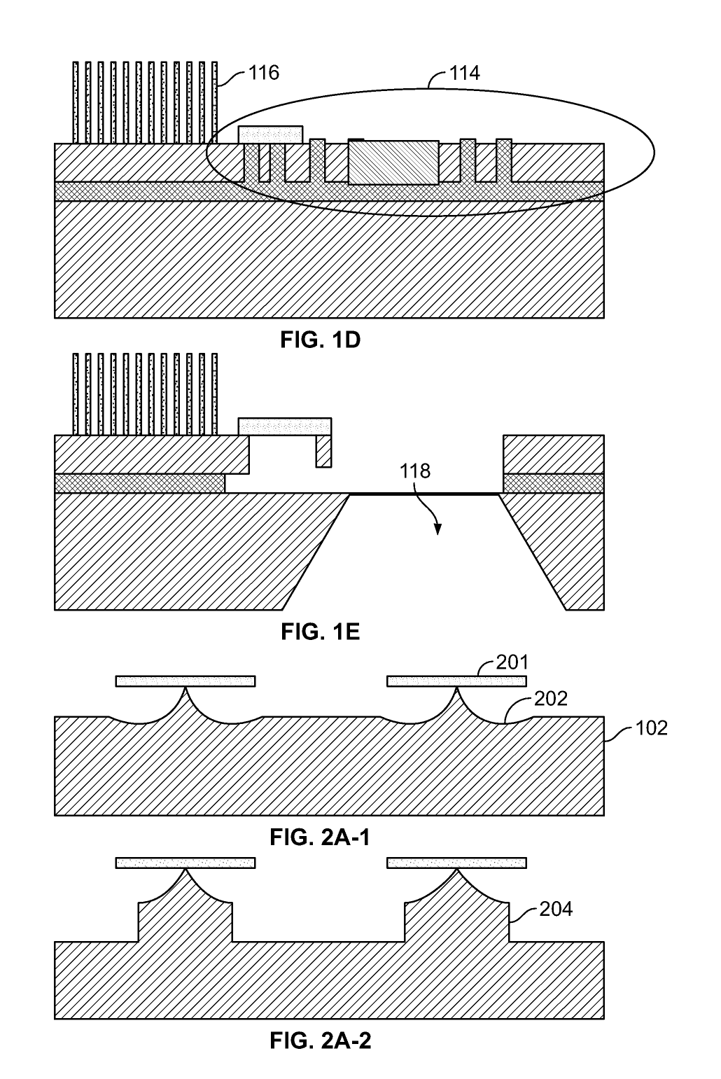

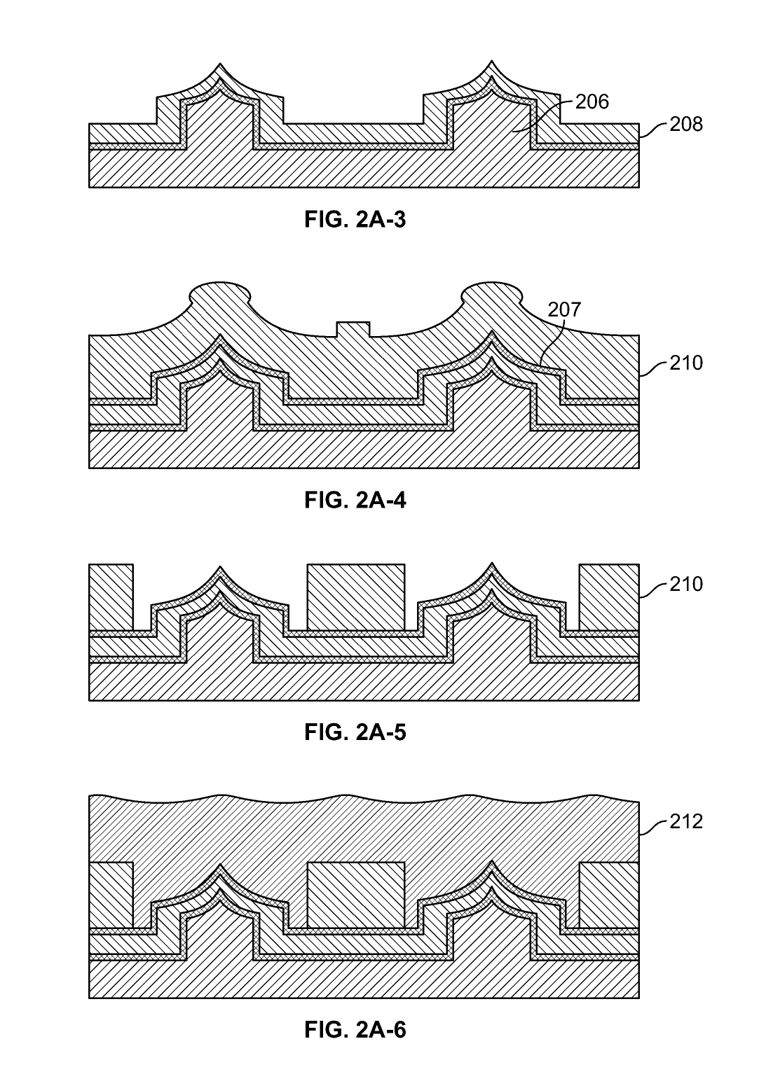

Referring to FIG. 1, there is shown a schematic configuration of a general overview of an integration process of a THz source for combining silicon FEA device on Silicon On Insulator (SOI) with MEMS actuation and LIGA grating in accordance with an embodiment of the present invention. The process begins with step (a) in which a single crystalline silicon (SCS layer) 102 is on top of a buried oxide, a.k.a. BOX layer 104, which itself is on top of an underlying substrate 106, preferably a Silicon Over Insulator (SOI) substrate 106. Then, in step (b), a silicon-tipped (or refractory metal) field emitter array (FEA) device area 108 is fabricated in the single crystalline silicon (SCS) layer 102 of a silicon-on-insulator (SOI) substrate 106. The SCS layer 102 is then further patterned to create a trench 109 surrounding the FEA region, and wet etch access holes to the buried oxide layer (BOX) 104. Then in step (c), hinges, preferably MEMS hinges, thermal and or mechanical actuators, and other mechanical members, as well as focusing and extraction electrode are created in area 110, preferably utilizing polysilicon surface micromachining. Following the completion of MEMS/FEA device area 114 in step (c), the wafer, i.e. SCS layer 102 is coated with a thick x-ray resist and the grating process, preferably LIGA grating is used to create metallic (any electroplatable metal) grating 116 of the suitable size, at a position adjacent to the FEA/MEMS device 114 as shown in step (d) of FIG. 1. In the near final step, at step (e) of FIG. 1, the FEA/MEMS device 114 is “released” by preferential etching of all of the sacrificial oxide layers in the device using an HF acid chemistry. This release of the SCS FEA surface or structure allows the SCS-FEA-MEMS surface to rotate out of plane, and frees the surface micromachined MEMS structures to actuate. Thereafter, thermal or mechanical MEMS actuators, or alternately external mechanical probes, can be preferably used to raise the now free SCS FEA surface into an out-of-plane vertical position. Mechanical support beams can also be raised to preferably lock the FEA surface into perpendicular position or alternately actuators can adjust the angle by precise increments. The FEA-MEMS device is then positioned into the desired alignment with the LIGA grating 116. Alternatively an optional back side etched opening 118 beneath the FEA device area 108 is also illustrated in FIG. 1. Details of steps (b), (c), (d) and (e) of FIG. 1 will be described in greater detail below with respect to FIGS. 2, 3, 4 and 5 respectively.

Referring to FIG. 2A, there is illustrated a schematic configuration of a detailed process to fabricate FEA device of the step (b) in FIG. 1. Initially, an oxide or alternatively, a Si₃N₄ layer 201 is deposited on the front and backside of the wafer, the SCS layer 102 as shown in part (a) of FIG. 2A. This layer is patterned on the front side with circular regions for field emitter tips 202. The tips 202 are fabricated by an isotropic etch gas such as Nitrogen Triflouride (NF3) or other gases that undercuts the circular oxide or nitride hardmask on the front side of the SOI substrate 106. Although not shown in FIG. 2A, a backside patterning of the layer 201 can also be optionally used to define windows for backside etching to the BOX layer 104 to aid in final device release. Etching can be accomplished using KOH-(Potassium Hydroxide) anisotropic wet etching or DRIE (Deep Reactive Ion Etching) used to undercut the back side of the SOI substrate 106. This will create the back side opening 118 beneath the FEA device area 108 as illustrated in FIG. 1.

A standard polysilicon etching gas such as a mixture of Chlorine and Hydrogen Bromide (Cl₂/HBr) etch gases (for a plasma etch) is preferably used to create a pedestal 204 around the tip 202 as illustrated in part (b) of FIG. 2A. Additionally, tips can be sharpened by thermal oxidation followed by wet stripping (not shown). Optionally, to protect the fabricated emitter tips 202 and the pedestals 204, as shown in part (c) of FIG. 2A, a thermal oxide (TOX) 206 and poly silicon layer 208 can be added to tip 202 and pedestal area 204 of the FEA. To aid in encapsulating and subsequently planarizing the FEA device area, an additional oxide layer 207 and a thick dummy polysilicon 210 is preferably added and patterned as shown in parts (d) and (e) of FIG. 2A.

After creating the FEA tips 202 and the pedestals 204, and dummy poly structures 210 i.e. part (e) of FIG. 2A, an etching of the SCS layer 102 is performed down to the BOX layer 104, this create trenches 109 and release holes 220. The trenches 109 and release holes 220 will be described in greater detail below with respect to FIG. 2B. The FEA 108 and SCS 109 trench regions are encapsulated with a flowable oxide 212 as illustrated in part (f). Then, etch back or CMP (chemo-mechanical polishing) of the filling oxide 212 is used to planarize the device down to the top of the dummy layer 210 and top of the surface of the surrounding SCS layer 102/110 area outside the PEA device area 108 as shown in part (g) of FIG. 2A. The PEA device area 108 is now encapsulated within the SCS layer 102.

A top-down view of the integrated device after step (g) of FIG. 2A is illustrated in FIG. 2B. A trench etch 109 through the SCS 102 down to the buried oxide 104 defines the grating region 214 preferably for LIGA grating, the anchor area 216 preferably for the MEMS hinge, and the FEA/MEMS device area 110 preferably for focusing electrodes, bond pads, hinge components. The trench 109 etch also defines release holes 220 that allow for undercutting of the BOX oxide 104 during the HF release process. The PEA region 108 is encapsulated inside the FEA/MEMS area 110.

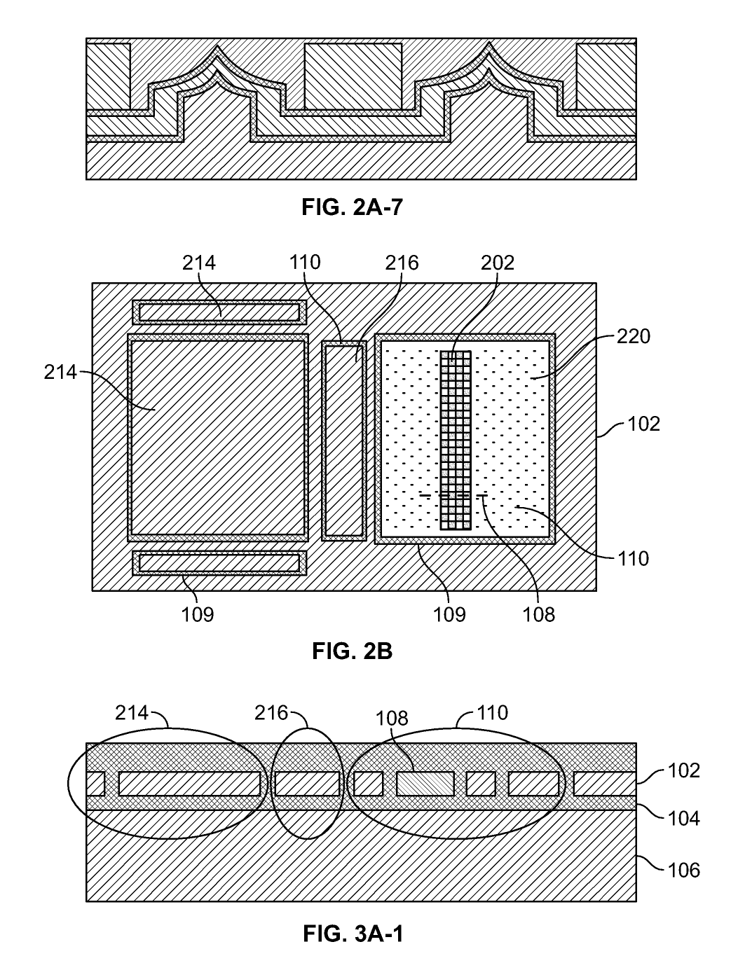

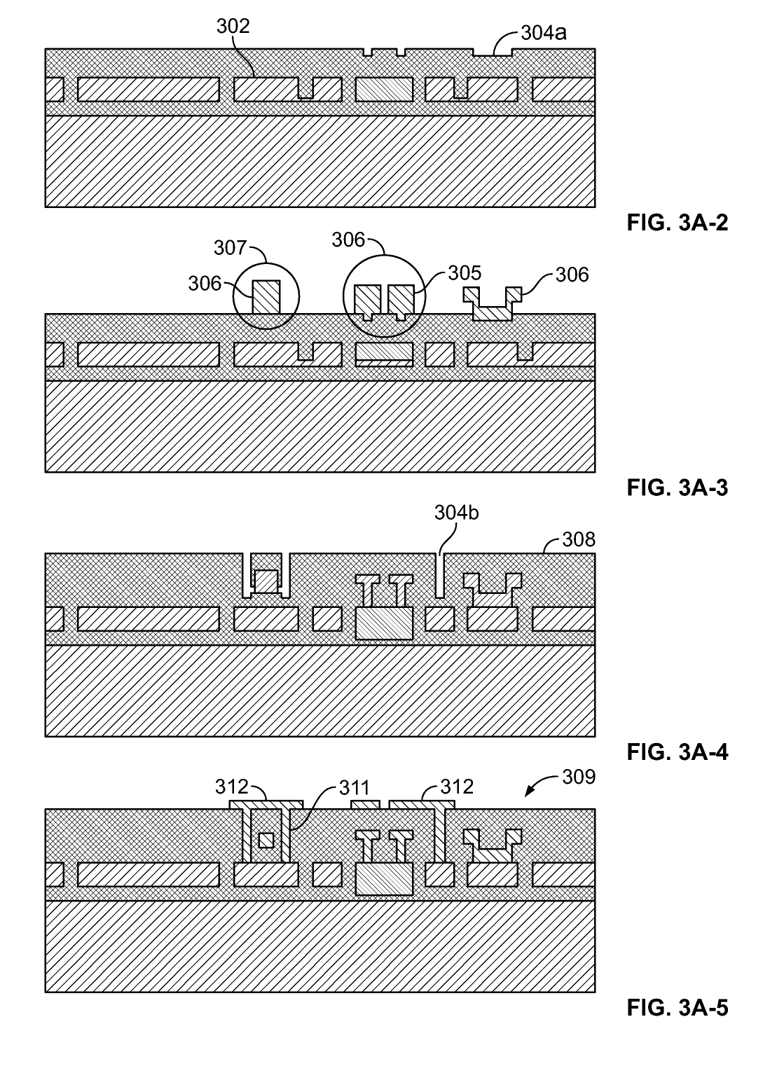

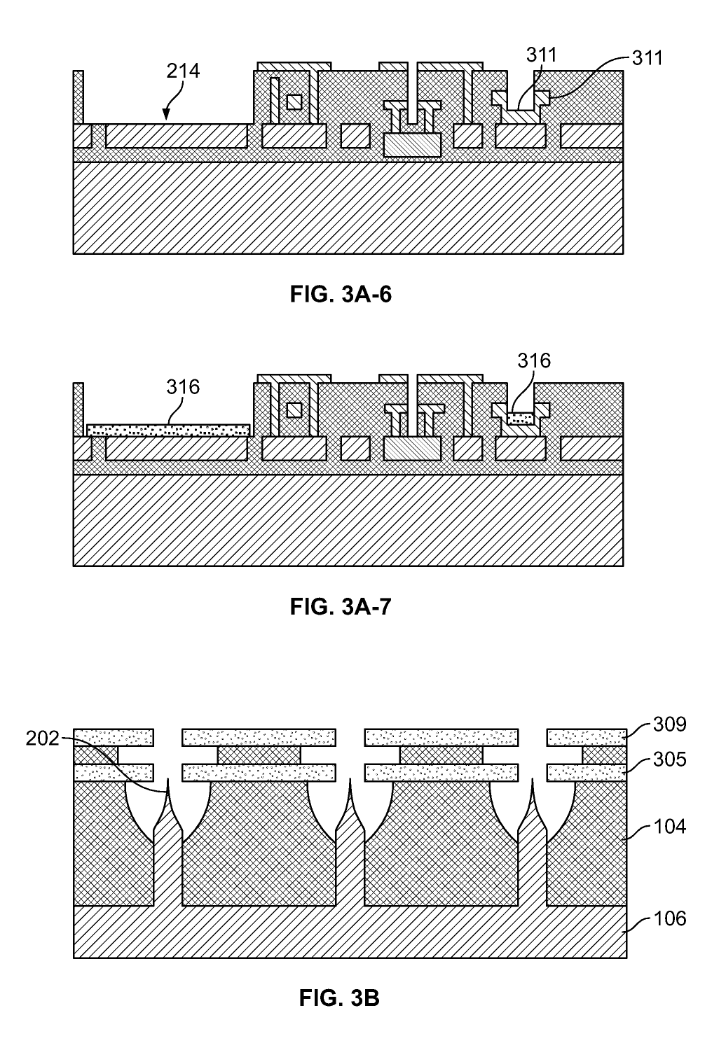

Following the device planarization (i.e. part (g) of FIG. 2A), the multi level polysilicon surface micromachining MEMS device 114 of the step (c) in FIG. 1 is carried out. The MEMS structures are built on top of the SCS surface 102, in the FEA/MEMS area 110 and anchor region 216, and can also be built in other unpopulated areas not shown. FIG. 3A, illustrates a schematic configuration of a detailed process for this fabrication. In the first step in this process includes depositing a sacrificial oxide layer film 302 as shown. The thickness of this film defines the isolation gap between the field emitters tips 202 and a first or lower FEA electrode 305 defined in the subsequent poly layer 306 as illustrated in FIG. 3B. Thereafter, anchors 304a are etched for the poly hinges, FEA electrodes, and to create electrical interconnects to the SCS surface in part (b) of FIG. 3A. Then, a doped polysilicon, i.e. poly1 306 is deposited and patterned for the FEA first electrode 305, hinge structure 307, and for other mechanical MEMS structures (braces, thermal and/or mechanical actuators) not shown, as illustrated in part (c) of FIG. 3A.

Thereafter, a second layer of oxide layer 308 is deposited for the dielectric between the first electrode 305 and a second or upper electrode 309, and upper gap for any additional hinges and anchors 304b are further etched through the oxide 308 and 302 to the SCS 102 or poly1 surface 306 as shown in parts (d) and (e) of FIG. 3A. The thickness of the second oxide film 308 defines a gap between the upper FEA electrode 309 and lower FEA electrode 305 as illustrated in FIG. 3B. Doped poly2 312 is then deposited and patterned for the upper electrode 309 and hinge cap 311 in part (t) of FIG. 3A. Additionally, other MEMS structures can be patterned in the poly1 306 and poly 2 312 layers. These structures (not shown) can act as actuators that move the FEA/MEMS device structure 114 into an out of plane position, or aid in its alignment. Thus, these mechanical structures created in the poly 1 layer 306 may also be preferably be used as electrical interconnects or vertical braces to the FEA device area.

Note that additional layers of poly can be added by repeating the above steps with respect to parts (a) through (f) as needed. Then, an oxide etch (not shown) is used to expose a region for LIGA fabrication 214, and also opens the oxide over the field emitter tips, and polysilicon bond pads 313 for future metallization as shown in part (g) of FIG. 3A. The steps described above with respect to parts (a) through (g) in FIG. 3A are known as the 3 poly process. Optionally, if a protective polysilicon 206 and/or 208 was used to cover the emitter tips 202 in part (c) of FIG. 2, then after the oxide etch, a final polysilicon etch (not shown) is used to expose the emitter tips 202. Finally, in part (h) of FIG. 3A, gold metallization 316 or other HF resistant metallization is deposited and patterned over the areas where oxide was removed in part (g) of FIG. 3A. This metallization is used for electrical contacts on the FEA/MEMS device 114.

Referring to FIG. 3B there is illustrated a top down view of FEA/MEMS device 114 after completion of surface micromachining with respect to parts (a)-(h) of FIG. 3A. As shown in FIG. 3B, is the patterned gold layer 316 both in the open area for LIGA fabrication and in the possible bond pad locations 313 of the FEA/MEMS device 114. Also, shown is the hinge structure 307, 311, and the vertical stack of the poly gate electrode 305 (bottom) and (top) focus electrode 309.

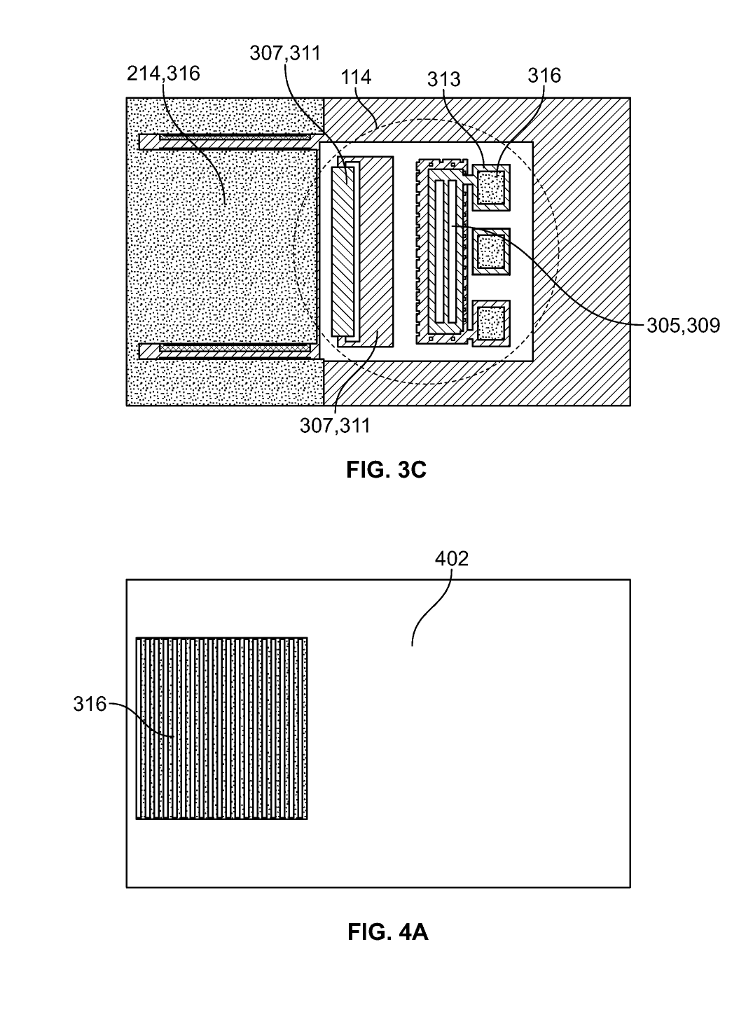

Following the MEMS/FEA device 114 completion as described above, a LIGA 116 fabrication process of step (d) of FIG. 1 is initiated to create metallic grating of the suitable size adjacent the MEMS/FEA device 114. This LIGA 116 fabrication process is illustrated in a schematic configuration of FIG. 4. Initially, a thick x-ray sensitive resist is spun completely onto the device surface 402 and exposed through a grating mask by a synchrotron x-ray beam line, and developed as shown in combined parts (a) and (b) of FIG. 4. In other words, a LIGA mask 116, which is basically a desired pattern you wish to construct and transfer it onto an x-ray opaque membrane to get the grating structure. Gold 316 is electroplated into the resist pattern 116 and polished back to the desired height to make a gold grating. The resist is stripped to have the LIGA grating 116 as desired as illustrated in part (c) of FIG. 4. The device is now ready for release and assembly.

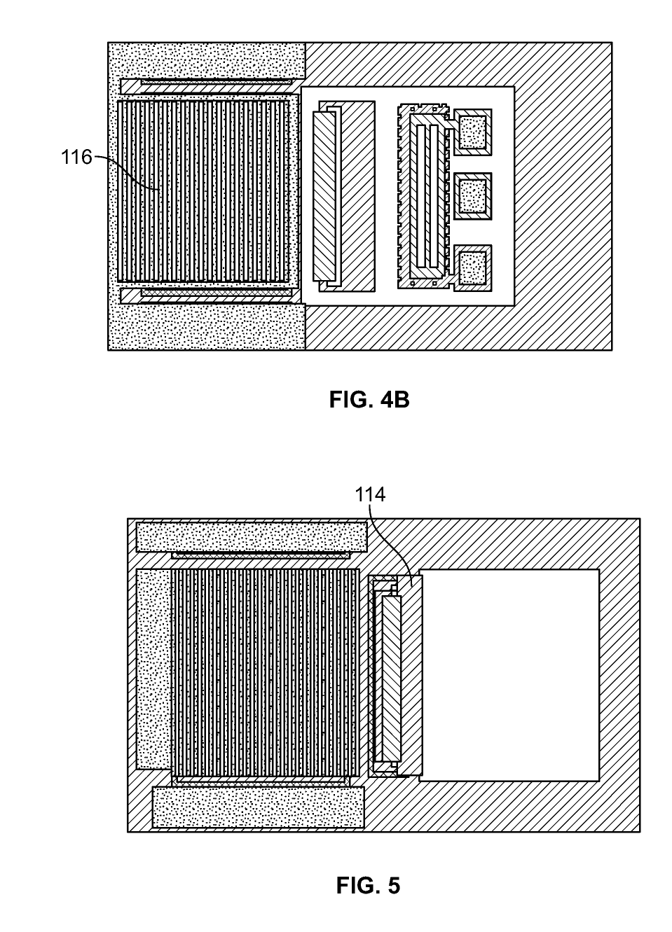

The MEMS/FEA device is “released” by immersion or soaking in an oxide etchant such as HF that removes the sacrificial oxide layers 302,308 between the polysilicon and the BOX layer 104. Lift up of the structure is accomplished using external probes from either the front (or back side if open) or using on-chip actuators and for lift off hooks patterned in the polysilicon layers. Hinged braces (not shown) lift and align the FEA/MEMS device 114 into a vertical out-of-plane position perpendicular to the grating surface 116 as shown in FIG. 5 and step (e) of FIG. 1. Alternatively, the hinged braces can be attached to actuators that adjust the angle of the FEA device 114 incrementally. So, actuators can also adjust the position of the FEA hinge for alternate angle adjustment.

In a preferred embodiment of the present invention, in order to aid in releasing the large FEA area it may be advantageous to optionally create the back side opening 118 beneath the FEA island 108 by defining a backside nitride window as discussed above with respect to FIGS. 1 and 2. So, after the surface micromachining completion in FIG. 3 part (h), a front side protection layer can be deposited and a back side KOH silicon etch can be performed (not shown) so that it stops on the BOX layer 104. The remaining steps in FIGS. 3 and 4 can then be completed. Note that the above steps provided for aiding in release for the large FEA area is not essential, but is considered desirable.

Even though various embodiments that incorporate the teachings of the present invention have been shown and described in detail herein, those skilled in the art can readily devise many other varied embodiments that still incorporate these teachings without departing from the spirit and the scope of the invention.

1. A method for fabrication of an integrated terahertz source comprising:
providing a SOI substrate having a buried oxide layer;
depositing a SCS layer with at least one trench portion substantially on said buried oxide of said SOI substrate;
constructing a FEA device substantially in said at least one trench portion of the SCS layer of the SOI substrate;
creating a grating on said at least one trench portion of the SCS layer adjacent to said FEA device; and
positioning of the FEA device in an angular alignment with the grating.

2. The method of claim 1 wherein said constructing step further comprising:
depositing at least one of an oxide layer or a nitride layer substantially on front and back side of the SOI substrate;
etching a portion of said at least one of the oxide layer or the nitride layer on the front side of the SOI substrate to fabricate a plurality of FEA tips of said FEA device;
depositing an additional layer of oxide and a dummy polysilicon to fill the plurality of the FEA tips and the said at least one trench portion of the SCS layer; and
planarizing through the SCS layer the filled FEA tips and the at least one trench portion of the SCS layer to the SOI substrate and the dummy polysilicon.

3. The method of claim 2 wherein said building step further comprises etching a portion of at least one of the oxide layer or the nitride layer on the back side of the SOI substrate to create a back side opening beneath the FEA device.

4. The method of claim 2 further comprising depositing a layer of sacrificial oxide on top of the plurality of the filled FEA tips and the at least one trench portion of the SCS layer after said planarizing step.

5. The method of claim 4 further comprising employing a multi level polysilicon surface micromachining on said at least one trench portion of the SCS layer to create areas for micro electro-mechanical system (MEMS) parts, electrodes and bond pads for the FEA device.

6. The method of claim 5 wherein said MEMS parts provide for electrical connection to the SCS layer.

7. The method of claim 5 wherein said MEMS parts comprise at least one of a hinge and an actuator.

8. The method of claim 5 further comprising etching said sacrificial oxide layer to expose the bond pads, the plurality of the filled FEA tips and the at least one trench portion of the SCS layer adjacent said FEA device.

9. The method of claim 8 further comprising depositing gold on the exposed bond pad, on the exposed plurality of the FEA tips and on the exposed at least one trench portion of the SCS layer adjacent said FEA device.

10. The method of claim 9 wherein said step of creating a grating further comprising:
forming a thick x-ray sensitive resist pattern onto the exposed at least one trench portion of the SCS layer adjacent said FEA device;
exposing said resist pattern through a grating mask;
electroplating said resist pattern with gold;
polishing said electroplated resist pattern to a desired dimension; and
stripping said gold grating mask.

11. The method of claim 10 wherein said grating mask is a LIGA grating.

12. The method of positioning step of claim 1 further comprising soaking the FEA device in an oxide etchant and lifting a portion of the FEA device.

13. The method of claim 1 wherein said FEA device is positioned into an vertical out-of-plane position perpendicular to the grating.

14. An integrated THz source structure comprising:
a SOI substrate having a buried oxide layer;
an SCS layer having at least one trench portion deposited substantially on said buried oxide layer of said SOI substrate;
a FEA device constructed substantially in said at least one trench portion of the SCS layer of the SOl substrate; and
a grating created on said at least one trench portion of the SCS layer adjacent to said FEA device, wherein said FEA device is positioned in an angular alignment with the grating.

15. The structure of claim 14 wherein said FEA device is positioned in vertical out-of-plane position perpendicular to the grating.

16. The structure of claim 14 wherein said FEA device comprise a plurality of FEA tips.

17. The structure of claim 14 further comprising electrodes, MEMS parts and bond pads positioned in an anchored region of said at least one trench portion of the SCS layer.

18. The structure of claim 17 wherein said MEMS parts provide for electrical connection to the SCS layer.

19. The structure of claim 17 wherein said MEMS parts comprise at least one of a hinge and an actuator.

20. The structure of claim 14 wherein said grating is a LIGA grating.
